(19) United States
(12) Patent Application Publication
(10) Pub. No.: US 2025/0351395 A1
(43) Pub. Date: Nov. 13, 2025

(54) SEMICONDUCTOR DEVICE

(71) Applicant: DENSO CORPORATION, Kariya-city (JP)

(72) Inventor: Keiichi KONDO, Kariya-city (JP)

(21) Appl. No.: 19/279,366

(22) Filed: Jul. 24, 2025

Related U.S. Application Data
(63) Continuation of application No. PCT/JP2023/040918, filed on Nov. 14, 2023.

(30) Foreign Application Priority Data
Jan. 30, 2023 (JP) 2023-012029

(51) Int. Cl. H10D 12/00; H10D 62/10

(52) U.S. Cl. CPC H10D 12/415; H10D 12/481; H10D 62/109; H10D 62/124

(57) ABSTRACT

A semiconductor substrate of a semiconductor device has: a deep region provided at a boundary between an element region and a peripheral region; a RESURF region provided in the peripheral region and shallower than the deep region; and a local region protruding downward from the RESURF region. The local region is disposed away from the deep region and has a bottom surface located deeper than the deep region.

### CROSS REFERENCE TO RELATED APPLICATIONS

The present application is a continuation application of International Patent Application No. PCT/JP2023/040918 filed on Nov. 14, 2023, which designated the U.S. and claims the benefit of priority from Japanese Patent Application No. 2023-012029 filed on Jan. 30, 2023. The entire disclosures of all of the above applications are incorporated herein by reference.

### TECHNICAL FIELD

The present disclosure relates to a semiconductor device.

### BACKGROUND

A semiconductor device includes a semiconductor substrate having an element region and a peripheral region. A reverse conducting IGBT structure is formed in the element region, and a p-type RESURF region is formed in the peripheral region.

### SUMMARY

A semiconductor device includes: a semiconductor substrate having an element region in which a device structure is formed and a peripheral region provided around the element region; an upper electrode provided on an upper surface of the semiconductor substrate; and a lower electrode provided on a lower surface of the semiconductor substrate. The semiconductor substrate includes: a drift region of a first conductivity type provided in the element region and the peripheral region; a deep region of a second conductivity type provided at a boundary between the element region and the peripheral region, at a position exposed at the upper surface of the semiconductor substrate; a RESURF region of a second conductivity type provided in the peripheral region, at a position exposed at the upper surface of the semiconductor substrate, the RESURF region extending from the deep region and shallower than the deep region; and a local region of a second conductivity type protruding downward from a bottom surface of the RESURF region, the local region being positioned away from the deep region and having a bottom surface at a position deeper than the deep region.

### BRIEF DESCRIPTION OF DRAWINGS

FIG. 1 is a schematic plan view illustrating a semiconductor device.

FIG. 2 is a schematic cross-sectional view taken along line II-II in FIG. 1.

FIG. 3 is a schematic enlarged cross-sectional view illustrating a peripheral region of a semiconductor substrate.

### DESCRIPTION OF EMBODIMENTS

A semiconductor device includes a semiconductor substrate having an element region and a peripheral region. In this semiconductor device, a reverse conducting IGBT structure is formed in the element region, and a p-type RESURF region is formed in the peripheral region. In addition, a p-type deep region that is deeper than the RESURF region is provided at the boundary between the element region and the peripheral region.

In a semiconductor device having a p-type deep region and a p-type RESURF region, when testing the static breakdown voltage, the electric field is concentrated in the deep region, within a negative resistance region after breakdown. Such an electric field concentration may cause element breakdown during the testing of static breakdown voltage, and deteriorate the testability of static breakdown voltage. The present specification provides a technique for suppressing such an element damage during a testing of static withstand voltage.

According to an aspect of the present disclosure, a semiconductor device includes: a semiconductor substrate having an element region in which a device structure is formed and a peripheral region provided around the element region; an upper electrode provided on an upper surface of the semiconductor substrate; and a lower electrode provided on a lower surface of the semiconductor substrate. The device structure refers to a structure formed on the semiconductor substrate in order to perform a specific function. The device structure is not particularly limited, and may be, for example, an IGBT structure or a MOSFET structure for achieving a switching function, a diode structure for achieving a rectifying function, or a combination of the structures. The semiconductor substrate may have: a drift region of a first conductivity type provided in the element region and the peripheral region; a deep region of a second conductivity type provided at a boundary between the element region and the peripheral region, at a position exposed at the upper surface of the semiconductor substrate; a RESURF region of a second conductivity type provided in the peripheral region, at a position exposed at the upper surface of the semiconductor substrate, the RESURF region extending from the deep region and shallower than the deep region; and a local region of a second conductivity type provided to protrude downward from a bottom surface of the RESURF region, the local region being disposed away from the deep region and having a bottom surface located deeper than the deep region.

In the semiconductor device, the local region that is deeper than the deep region is provided to protrude downward from the bottom surface of the RESURF region. Such a local region can bear an electric field during a static pressure test. This reduces the electric field concentration in the deep region during a testing of static breakdown voltage. As a result, in the semiconductor device, element destruction during a testing of static breakdown voltage is suppressed.

A semiconductor device of this embodiment will be described below with reference to the drawings. For the purpose of clarity in the drawings, reference numerals may be attached to only some of the repeatedly arranged components.

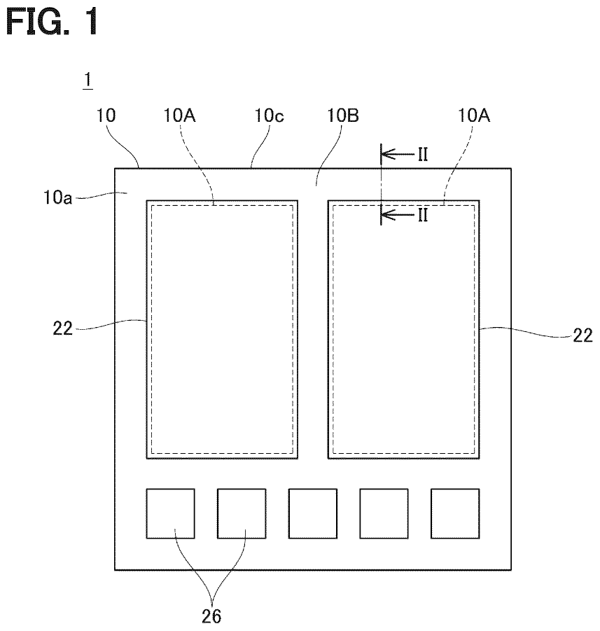

A semiconductor device 1 shown in FIG. 1 has a semiconductor substrate 10. The material of the semiconductor substrate 10 is not particularly limited, but may be, for example, silicon, silicon carbide, or a nitride semiconductor. Two upper electrodes 22 and plural signal electrodes 26 are provided on the upper surface 10a of the semiconductor substrate 10. Instead of the two upper electrodes 22, one upper electrode 22 may be provided on the upper surface 10a of the semiconductor substrate 10. Each of the signal electrodes 26 is an interface for inputting and outputting gate signals and various sensor signals. The semiconductor substrate 10 has, in the area below each of the upper electrodes 22, an element region 10A in which an IGBT structure that exerts a switching function is formed. Alternatively, a structure that exhibits a specific function is formed in the element region 10A. For example, a MOSFET structure that exhibits a switching function may be formed, or a diode structure that exhibits a rectification function may be formed. Alternatively, a reverse conducting IGBT structure that combines an IGBT structure and a diode structure may be formed. The semiconductor substrate 10 further has a peripheral region 10B around the element region 10A. The peripheral region 10B is disposed between the element region 10A and an outer end surface 10c of the semiconductor substrate 10. As will be described later, a breakdown voltage structure for improving the breakdown voltage of the semiconductor device 1 is provided in the peripheral region 10B. In the following description, the side closer to the outer end surface 10c is referred to as the outer peripheral side, and the opposite side (farther from the outer end surface 10c) is referred to as the inner peripheral side.

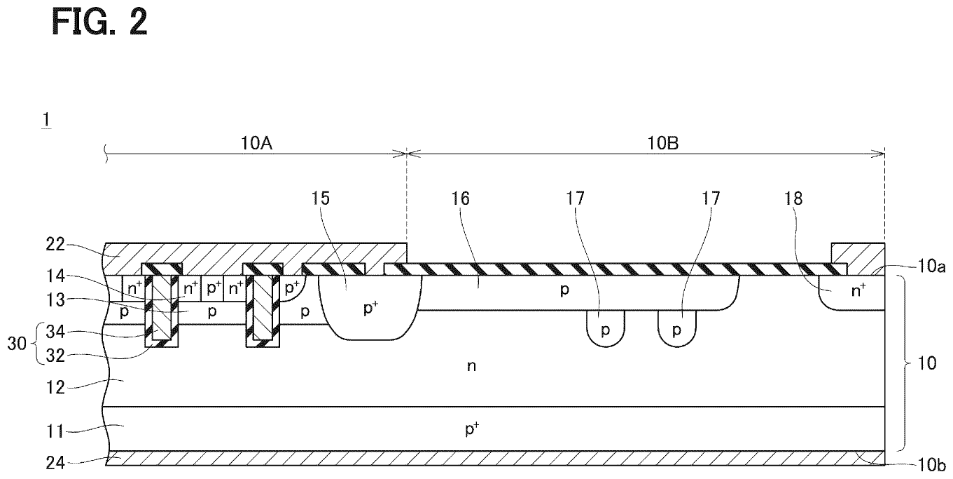

As shown in FIG. 2, a lower electrode 24 is provided on the lower surface 10b of the semiconductor substrate 10. The lower electrode 24 covers the entire lower surface 10b of the semiconductor substrate 10. Plural trench gates 30 are formed in the upper layer of the element region 10A of the semiconductor substrate 10. Each of the trench gates 30 has a gate insulating film 32 and a gate electrode 34. The gate insulating film 32 is provided to cover the inner surface of trench formed in the upper layer of the element region 10A of the semiconductor substrate 10. The gate electrode 34 fills the trench and is insulated from the semiconductor substrate 10 by the gate insulating film 32.

The semiconductor substrate 10 has a p+ type collector region 11, an n-type drift region 12, a p-type body region 13, plural n+ type emitter regions 14, a p-type deep region 15, a p-type RESURF region 16, plural p-type local regions 17, and an n+ type equipotential ring region 18.

The collector region 11 is provided in both the element region 10A and the peripheral region 10B of the semiconductor substrate 10, and is disposed in a lower layer of the semiconductor substrate 10. The collector region 11 is in ohmic contact with the lower electrode 24.

The drift region 12 is provided in both the element region 10A and the peripheral region 10B of the semiconductor substrate 10, and is disposed on the collector region 11. The drift region 12 is in contact with the lower surface and the lower side surface of each of the trench gates 30.

The body region 13 is provided in the element region 10 A of the semiconductor substrate 10, and is disposed in an upper layer of the semiconductor substrate 10. The body region 13 is in contact with the side surface of each of the trench gates 30 and separates the drift region 12 from the emitter region 14. The body region 13 is in ohmic contact with the upper electrode 22 via a contact region in which the concentration of p-type impurities is adjusted to a high level.

Each of the emitter regions 14 is provided in the element region 10A of the semiconductor substrate 10 and is disposed at a position exposed from the upper surface 10a of the semiconductor substrate 10. Each of the emitter regions 14 is in contact with the upper side of the corresponding trench gate 30. Each of the emitter regions 14 is in ohmic contact with the upper electrode 22.

The deep region 15 is provided at the boundary between the element region 10A and the peripheral region 10B of the semiconductor substrate 10, and is disposed at a position exposed from the upper surface 10a of the semiconductor substrate 10. In a plan view of the semiconductor substrate 10, the deep region 15 is disposed to surround the periphery of the body region 13 along the boundary between the element region 10A and the peripheral region 10B. The deep region 15 is a diffusion region formed by introducing p-type impurities into the upper layer of the semiconductor substrate 10 using ion implantation technology. The deep region 15 is in contact with both the body region 13 and the RESURF region 16, and is formed deeper than both the body region 13 and the RESURF region 16. The deep region 15 is in ohmic contact with the upper electrode 22.

The RESURF region 16 is provided in the peripheral region 10B of the semiconductor substrate 10 and is disposed at a position exposed from the upper surface 10a of the semiconductor substrate 10. The RESURF region 16 is in contact with the deep region 15 and extends from the deep region 15 in a direction away from the element region 10A, that is, toward the outer peripheral side. The RESURF region 16 is disposed to surround the deep region 15 in a plan view of the semiconductor substrate 10. The RESURF region 16 is a diffusion region formed by introducing p-type impurities into the upper layer of the semiconductor substrate 10 using ion implantation technology. The concentration of p-type impurities in the RESURF region 16 is lower than the concentration of p-type impurities in the deep region 15. The concentration of the p-type impurity in the RESURF region 16 decreases continuously or stepwise toward the outer peripheral side.

The local region 17 is provided in the peripheral region 10B of the semiconductor substrate 10 and is disposed in contact with the bottom surface of the RESURF region 16. The local region 17 is provided to protrude downward from the bottom surface of the RESURF region 16. The local region 17 is disposed away from the deep region 15 and has a bottom surface located deeper than the deep region 15. The local region 17 is a diffusion region formed by introducing the p-type impurity to have a predetermined depth from the upper surface 10a of the semiconductor substrate 10 using ion implantation technique. The concentration of p-type impurities in each of the local regions 17 is lower than the concentration of p-type impurities in the deep region 15. Instead of the multiple local regions 17, only one local region 17 may be provided.

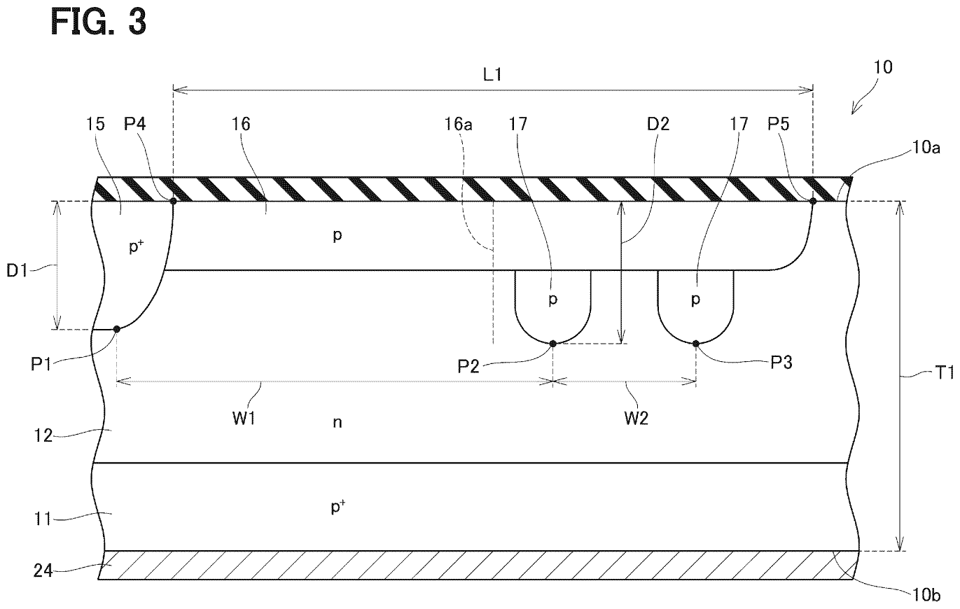

The relative positional relationship and shapes of the regions will be described with reference to FIG. 3. The thickness T1 of the semiconductor substrate 10 is a length measured between the upper surface 10a and the lower surface 10b of the semiconductor substrate 10 in the thickness direction of the semiconductor substrate 10. The depth D1 of the deep region 15 is a length measured in the thickness direction of the semiconductor substrate 10, between the upper surface 10a of the semiconductor substrate 10 and the deepest part of the deep region 15. In this embodiment, the deepest part of the deep region 15 is the bottom surface of the deep region 15 formed parallel to the surface direction of the semiconductor substrate 10, reflecting the wide ion implantation. The depth D2 of the local region 17 is a length measured between the upper surface 10a of the semiconductor substrate 10 and the deepest part of the local region 17. In this embodiment, the deepest part of the local region 17 is a downward apex P2 of the local region 17, reflecting the local ion implantation. The distance W1 between the deep region 15 and the local region 17 closest to the element region 10A, of the multiple local regions 17, is a length measured as the shortest distance between a bending point P1 of the deep region 15 and the downward apex P2 of the local region 17. The bending point P1 of the deep region 15 is a junction between the flat bottom surface and the curved side of the deep region 15. The distance W2 between the local regions 17 adjacent to each other is a length measured as the shortest distance between the downward apex P2 and a downward apex P3 of the adjacent local region 17. When the local region 17 is formed to have a flat bottom surface, the bending point of the local region 17 may be used to measure the distance W1, W2. The length L1 of the RESURF region 16 is measured as the shortest distance between an inner end point P4 of the RESURF region 16 and an outer end point P5 of the RESURF region 16. The inner end point P4 of the RESURF region 16 is defined by a contact point where the junction surface between the RESURF region 16 and the deep region 15 comes into contact with the upper surface 10a of the semiconductor substrate 10. The outer end point P5 of the RESURF region 16 is defined by a contact point where the junction surface between the RESURF region 16 and the drift region 12 comes into contact with the upper surface 10a of the semiconductor substrate 10.

In the semiconductor device 1, the depth D2 of the local region 17 is greater than the depth D1 of the deep region 15. In the semiconductor device 1, the distance W1 is equal to or greater than the thickness T1 of the semiconductor substrate 10, and the distance W2 is equal to or less than the thickness T1 of the semiconductor substrate 10. In the semiconductor device 1, at least one of the local regions 17 is positioned on the outer side of the center position 16a of the RESURF region 16, i.e., the position to be L1/2, when viewed in a direction away from the element region 10A, i.e., in a direction connecting the inner peripheral side and the outer peripheral side. Both of the two local regions 17 are disposed on the outer side of the center position 16a of the RESURF region 16. Alternatively, among the multiple local regions 17, the outer local region 17 may be positioned on the outer side of the center position 16a of the RESURF region 16, and the inner local region 17 may be positioned on the inner side of the center position 16a of the RESURF region 16.

As shown in FIG. 2, the equipotential ring region 18 is provided in the peripheral region 10B of the semiconductor substrate 10 and is disposed at a position exposed from the upper surface 10a of the semiconductor substrate 10. In a plan view, the equipotential ring region 18 is disposed to surround the element region 10A and the peripheral region 10B along the outer peripheral edge of the semiconductor substrate 10. The equipotential ring region 18 is in ohmic contact with an EQR electrode formed on the upper surface 10a of the semiconductor substrate 10. The EQR electrode is fixed to the same potential as the lower electrode 24.

In this manner, in the semiconductor device 1, an IGBT structure consisting of the trench gates 30 and various semiconductor regions is formed in the element region 10A of the semiconductor substrate 10. The RESURF region 16 is formed as a voltage-resistant structure in the peripheral region 10B of the semiconductor substrate 10. In the semiconductor device 1, the deep region 15 that is diffused deeper than the body region 13 and the RESURF region 16 is formed at the boundary between the element region 10A and the peripheral region 10B.

For the semiconductor device 1, a static breakdown voltage is tested by applying a voltage between the upper electrode 22 and the lower electrode 24 such that the lower electrode 24 is more positive than the upper electrode 22 while the IGBT structure is turned off (i.e., no gate-on voltage is applied to each of the trench gates 30). In the testing of static breakdown voltage, a breakdown is caused in the semiconductor device 1, and the quality of the semiconductor device 1 is judged based on the measured breakdown voltage.

For example, in a comparative example in which multiple local regions 17 are not provided, when a static breakdown voltage is tested, an electric field is concentrated in the deep region 15 in the negative resistance region after breakdown. In the comparative example, large current flows through the deep region 15, which may result in destruction of the element.

In contrast, in the semiconductor device 1 of this embodiment, the depth D2 of each local region 17 is greater than the depth D1 of the deep region 15, so that each of the local regions 17 can bear the electric field during the testing of static breakdown voltage. This reduces the electric field concentration in the deep region 15 during the testing of static breakdown voltage. As a result, in the semiconductor device 1, element destruction during the testing of static withstand voltage is suppressed.

In the semiconductor device 1, the distance W1 between the local region 17 that is closest to the element region 10A and the deep region 15 is equal to or greater than the thickness T1 of the semiconductor substrate 10. At least one of the local regions 17 is disposed on the outer side of the center position 16a of the RESURF region 16 in a direction away from the element region 10A. That is, each of the local regions 17 is disposed at a sufficient distance from the deep region 15. Therefore, in the negative resistance region after breakdown, the current flowing in the peripheral region 10B is dispersed, so that the occurrence of element destruction is effectively suppressed. The plural local regions 17 are provided to reduce the electric field concentration in the deep region 15. Therefore, the static breakdown voltage of the semiconductor device 1 can be improved.

In the semiconductor device 1, the distance W2 between the local regions 17 is equal to or smaller than the thickness T1 of the semiconductor substrate 10. In other words, the local regions 17 are arranged so as not to be too far apart from each other. As a result, when the semiconductor device 1 is turned off, the equipotential lines formed in the peripheral region 10B are smoothed, and excessive concentration of the electric field at locations corresponding to each of the local regions 17 is suppressed. As a result, the deterioration of the static breakdown voltage of the semiconductor device 1 is suppressed.

The embodiment is merely example and does not limit the scope of claims. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A semiconductor device comprising:
a semiconductor substrate having an element region in which a device structure is formed and a peripheral region provided around the element region;
an upper electrode provided on an upper surface of the semiconductor substrate; and
a lower electrode provided on a lower surface of the semiconductor substrate, wherein
the semiconductor substrate includes:
a drift region of a first conductivity type provided in the element region and the peripheral region;
a deep region of a second conductivity type provided at a boundary between the element region and the peripheral region, at a position exposed at the upper surface of the semiconductor substrate;
a RESURF region of a second conductivity type provided in the peripheral region, at a position exposed at the upper surface of the semiconductor substrate, the RESURF region extending from the deep region and shallower than the deep region; and
a local region of a second conductivity type protruding downward from a bottom surface of the RESURF region, the local region being positioned away from the deep region and having a bottom surface at a position deeper than the deep region.

2. The semiconductor device according to claim 1, wherein a distance between the deep region and the local region is equal to or greater than a thickness of the semiconductor substrate.

3. The semiconductor device according to claim 1, wherein the local region is located on an outer side of a center position of the RESURF region when viewed in a direction away from the element region.

4. The semiconductor device according to claim 1, wherein the local region is one of a plurality of local regions.

5. The semiconductor device according to claim 4, wherein a distance between the local regions adjacent to each other is equal to or smaller than a thickness of the semiconductor substrate.
